(19) United States
(12) Patent Application Publication
(10) Pub. No.: US 2015/0125980 A1
(43) Pub. Date: May 7, 2015

(54) METHOD FOR PRODUCING M-PLANE NITRIDE-BASED LIGHT-EMITTING DIODE

(71) Applicants: MITSUBISHI CHEMICAL CORPORATION, Chiyoda-ku (JP); SEOUL VIOSYS CO., LTC., Ansan-si (KR)

(72) Inventors: Kaori Kurihara, Ushiku-shi (JP); Yutaro Takeshita, Ushiku-shi (JP); Kenji Shimoyama, Ushiku-shi (JP); Shinji Takai, Ushiku-shi (JP)

(73) Assignees: MITSUBISHI CHEMICAL CORPORATION, Chiyoda-ku (JP); SEOUL VIOSYS CO., LTD., Ansan-si (KR)

(21) Appl. No.: 14/582,591

(22) Filed: Dec. 24, 2014

Related U.S. Application Data
(63) Continuation of application No. PCT/JP2013/067267, filed on Jun. 24, 2013.

(30) Foreign Application Priority Data
Jun. 25, 2012 (JP) 2012-141778
Aug. 9, 2012 (JP) 2012-177193
Mar. 11, 2013 (JP) 2013-048240

(51) Int. Cl. H01L 33/00; H01L 33/14; H01L 33/42

(52) U.S. Cl. CPC H01L 33/0075; H01L 33/42; H01L 33/145; H01L 2933/0066; H01L 2933/0016
USPC 438/45

(57) ABSTRACT

Provided is a novel method for producing an m-plane nitride-based LED, the method making it possible to obtain an m-plane nitride-based LED reduced in forward voltage. The method comprising (i) a step of forming an active layer consisting of a nitride semiconductor over an n-type nitride semiconductor layer in which an angle between the thickness direction and the m-axis of a hexagonal crystal is 10 degrees or less, (ii) a step of forming an AlGaN layer doped with a p-type impurity over the active layer, (iii) a step of forming a contact layer consisting of InGaN is formed on the surface of the AlGaN layer, and (iv) a step of forming an electrode on the surface of the contact layer.

### CROSS-REFERENCE TO RELATED APPLICATION

This is a continuation of International Application PCT/JP2013/067267, filed on Jun. 24, 2013, and designated the U.S., (and claims priority from Japanese Patent Application 2012-141778 which was filed on Jun. 25, 2012, Japanese Patent Application 2012-177193 which was filed on Aug. 9, 2012 and Japanese Patent Application 2013-048240 which was filed on Mar. 11, 2013,) the entire contents of which are incorporated herein by reference.

### TECHNICAL FIELD

The present invention relates to a nitride-based light-emitting diode (nitride-based LED) which has a light-emitting structure formed of nitride semiconductors. Nitride semiconductors are also called nitride-based Group III-V element compound semiconductors, gallium nitride (GaN)-based semiconductors, or the like, and are compound semiconductors represented by the general formula AlₓGa_{y}In_{1-x-y}N (0≦x≦1, 0≦y≦1, and 0≦x+y≦1), (Al,Ga,In)N, or the like. It is known that the semiconductors have a crystal structure belonging to the hexagonal crystal systems. A typical nitride-based LED is equipped with a light-emitting structure of a double hetero-pn-junction type and includes an active layer which is a multiple-quantum-well layer having a multilayered film structure obtained by alternately superposing InGaN well layers and (In)GaN barrier layers.

### BACKGROUND ART

Research and development have been made on m-plane nitride-based LEDs obtained by using an m-plane GaN substrate (to which an off-angle of at most about 10° may have been imparted), which is a nonpolar substrate, and superposing an n-type layer, an active layer, and a p-type layer in the m-axis direction of the hexagonal crystals to form a double hetero-pn-junction structure so that the quantum confined Stark effect (QCSE) is not induced (Non-Patent Document 1).

A method for producing an m-plane nitride-based LED has been proposed in order to improve luminescent efficiency, an essential point of the method residing in that a p-type nitride semiconductor layer is formed on an active layer at a growth temperature lower than 900° C., thereby inhibiting the active layer from suffering thermal damage (Patent Document 3).

In the course of putting nitride-based LEDs that utilizes a c-plane sapphire substrate into practical use, investigations were made on optimization of, for example, the crystal composition of a p-type layer including a contact layer (nitride semiconductor layer, on the surface of which an ohmic electrode is to be formed), the kind and concentration of an impurity to be added, and the layer thickness, for the purpose of reducing the forward voltage (Patent Document 1).

Attempts have been made for long to omit the post annealing for activating p-type impurities, e.g., Mg (magnesium) and Zn (zinc), added to nitride semiconductors (annealing conducted using an RTA device or the like after the wafer is taken out of the epitaxial growth furnace) and to thereby heighten the efficiency of producing nitride-based LEDs. In connection with this purpose, various ideas have been proposed with respect to the control of the substrate temperature during the period from immediately after completion of the growth of a p-type layer (formed last in the epitaxial growth step) of a nitride-based LED to the time when the substrate temperature is lowered to 400° C. or below and to the control of the atmosphere inside the growth furnace (Patent Document 2).
Patent Document 1: Japanese Patent Application Laid-open NO. H10-242587
Patent Document 2: Japanese Patent Application Laid-open NO. 2005-235960
Patent Document 3: Japanese Patent Application Laid-open NO. 2010-245444
Non-Patent Document: Mathew C. Schmidt et al., Japanese Journal of Applied Physics, Vol. 46, No. 7, 2007, pp. L126-L128

### DISCLOSURE OF THE INVENTION

For reducing the power consumption of illuminators or display devices which employ LEDs, it is important to reduce the forward voltage (i.e., operating voltage) of the LEDs. It is expected that almost all of the incandescent light bulbs and fluorescent lamps will be replaced with LED illuminators in the near feature. In that case, only a 0.1-V difference in the forward voltage of each LED greatly affects the amount of electric power to be consumed by the whole society.

In particular, nitride-based LEDs including a GaN substrate on which a light-emitting structure has been formed have few crystal defects and high heat resistance and, hence, can be used in such a manner that a high current is applied to each LED chip. The higher the current applied to each LED, the more the quantity of generated heat changes with even a slight difference in the forward voltage thereof. Consequently, to reduce forward voltage is a more important subject. In case where the quantity of heat to be generated can be reduced, the heat sink necessary for cooling the LEDs can have a reduced capacity, resulting in a high degree of freedom in the design of devices employing the LEDs.

However, investigations on p-type layer optimization for reducing forward voltage have been made so far mainly in c-plane nitride-based LEDs only. Similar investigations on m-plane nitride-based LEDs have not been sufficiently made yet.

The invention has been achieved in view of such circumstances, and a major object thereof is to provide a novel method for producing an m-plane nitride-based LED, the method making it possible to obtain an m-plane nitride-based LED reduced in forward voltage.

The embodiments of the invention include the following methods for producing an m-plane nitride-based light-emitting diode.

(1) A method for producing an m-plane nitride-based light-emitting diode, the method comprising (i) a step of forming an active layer consisting of a nitride semiconductor over an n-type nitride semiconductor layer in which an angle between the thickness direction and the m-axis of a hexagonal crystal is 10 degrees or less, (ii) a step of forming an AlGaN layer doped with a p-type impurity over the active layer, (iii) a step of forming a contact layer consisting of InGaN is formed on the surface of the AlGaN layer, and (iv) a step of forming an electrode on the surface of the contact layer.

(2) The production method according to (1) above, wherein the contact layer has a thickness of 20 nm or less.

(3) The production method according to (1) or (2) above, which comprises, before forming the AlGaN layer, a step of forming an electron-blocking layer is formed over the active layer, the electron-blocking layer having a thickness of 50 nm or less and consisting of a nitride semiconductor that has a higher band gap energy than the AlGaN layer.

(4) The production method according to any one of the items (1) to (3), wherein the AlGaN layer comprises AlₓGa₁₋ₓN (0.01≦x≦0.05).

(5) The production method according to any one of (1) to (4) above, wherein the active layer comprises a well layer and a barrier layer, and the band gap energy of the contact layer is higher than the band gap energy of the well layer.

(6) The production method according to any one of (1) to (5) above, wherein the electrode comprises a conductive oxide.

(7) The production method according to (6) above, wherein the conductive oxide comprises ITO (indium-tin oxide).

(8) The production method according to any one of (1) to (7) above, wherein the active layer comprises an InGaN well layer and a barrier layer, and the InGaN well layer has a thickness of 6 to 12 nm.

(9) The production method according to any one of (1) to (8) above, wherein the contact layer is formed at a growth rate of 2 to 3 nm/min.

(10) The production method according to any one of (1) to (10) above, wherein the contact layer is grown at an NH₃/TMG ratio of 40,000 to 50,000.

(11) The production method according to anyone of (1) to (11) above, wherein the steps (ii) and (iii) are conducted in the same MOVPE growth furnace, and the AlGaN layer is not taken out of the MOVPE growth furnace during the period from the end of the step (ii) to the start of the step (iii).

(12) The production method according to (11) above, wherein the AlGaN layer and the contact layer are not subjected to post-annealing during the period from the end of the step (iii) to the start of the step (iv).

The nitride semiconductor layer in which the angle between the thickness direction and the m-axis of the hexagonal crystal is 10 degrees or less, according to (1) above, is a nitride semiconductor layer in which, in cases when the surface thereof is a flat surface, the angle between the flat surface and the m-plane is 10 degrees or less. In nitride semiconductor layers epitaxially grown on an m-plane GaN substrate having an off-angle of 10 degrees or less, the angle between the thickness direction and the m-axis is usually 10 degrees or less.

By using the above-described production methods according to embodiments of the invention, an m-plane nitride-based light-emitting diode reduced in forward voltage can be obtained.

### BRIEF DESCRIPTION OF THE DRAWINGS

FIG. 1 is a set of drawings which shows an m-plane nitride-based LED viewed from the upper surface side, with FIG. 1 (a) being a schematic view thereof and FIG. 1 (b) being a photomicrograph thereof (photograph as a drawing substitute).

FIG. 2 is a schematic view which illustrates the epitaxial layer structure possessed by the m-plane nitride-based LEDs produced in Experiment 1-1 and Experiment 3-6.

FIG. 3 is a schematic view which illustrates the epitaxial layer structure possessed by the m-plane nitride-based LEDs produced in Experiment 1-2 to Experiment 1-3, Experiment 2-1 to Experiment 2-3, and Experiment 3-1 to Experiment 3-5.

FIG. 4 is a set of drawings which shows an m-plane nitride-based LED viewed from the upper surface side, with FIG. 4 (a) being a schematic view thereof and FIG. 4 (b) being a photomicrograph thereof (photograph as a drawing substitute).

FIG. 5 is a schematic view which illustrates the epitaxial layer structure possessed by the m-plane nitride-based LED experimentally produced in Experiment 4.

FIG. 6 is a profile which shows the depth-direction distribution of concentrations of Al, In, and Mg in the vicinity of the surface of an epitaxial wafer, obtained by SIMS (secondary-ion mass spectroscopy). With respect to each element, the solid line represents a concentration distribution in an epitaxial wafer having an InGaN contact layer disposed therein, while the broken line represents a concentration distribution in an epitaxial wafer having no InGaN contact layer disposed therein.

FIG. 7 is an SEM image of the back surface of an m-plane GaN substrate which has undergone RIE (photograph as a drawing substitute).

FIG. 8 is a luminescent spectrum of an m-plane nitride-based LED.

FIG. 9 is a graph which shows the I-L characteristics of an m-plane nitride-based LED.

FIG. 10 is a graph which shows the current density dependence of external quantum efficiency of an m-plane nitride-based LED.

FIG. 11 is a drawing for explaining the off-angle of an m-plane GaN substrate.

FIG. 12 is a cross-sectional view which shows an example of the structure of an m-plane nitride-based LED according to the invention.

### BEST MODE FOR CARRYING OUT THE INVENTION

In this description, the term “InGaN” means a mixed crystal of InN and GaN, and “AlGaN” means a mixed crystal of AlN and GaN. Furthermore, the term “InAlGaN” means a mixed crystal of InN, AlN, and GaN.

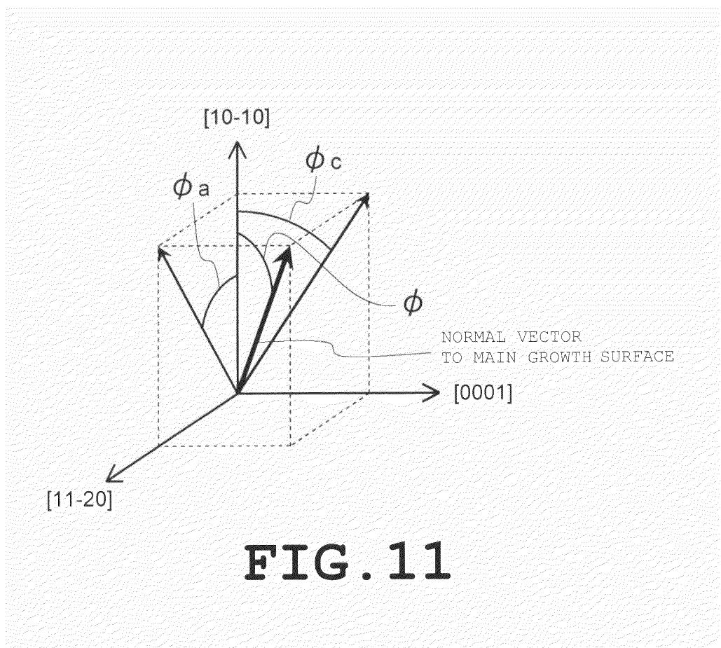

In this description, an off-angled m-plane GaN substrate is often referred to. The off-angle of an m-plane GaN substrate, as shown in FIG. 11, is the angle φ between [10-10] and the normal vector to the main growth surface (main surface used for epitaxial growth) of the substrate. The +c-direction off-angle φ_{c} of the m-plane GaN substrate is the angle φ_{c} between [10-10] and the projection obtained by projecting the normal vector to the main growth surface on the a-plane (plane orthogonal to [11-20]). In cases when the projection has a [0001] component (+c component), the value of φ_{c} is plus. In contrast, in cases when the projection has a [000-1] component (−c component), the value of φ_{c} is minus.

The method for producing an m-plane nitride-based light-emitting diode according to a preferable embodiment of the invention comprises the following four steps:

(i) a step in which an active layer constituted of a nitride semiconductor is formed over an n-type nitride semiconductor layer in which the angle between the thickness direction and the m-axis of the hexagonal crystal is 10 degrees or less;

(ii) a step in which an AlGaN layer doped with a p-type impurity is formed over the active layer;

(iii) a step in which a contact layer constituted of InGaN is formed on the surface of the AlGaN layer; and

(iv) a step in which an electrode is formed on the surface of the contact layer.

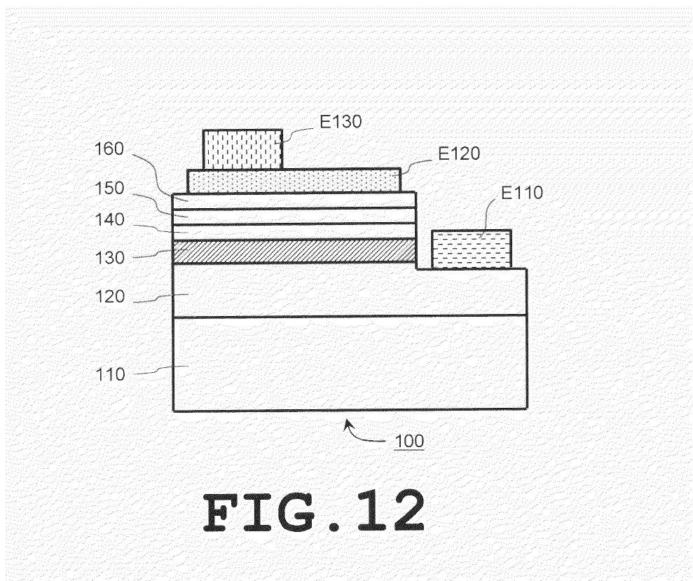

FIG. 12 shows an example of the structure of an m-plane nitride-based light-emitting diode obtained by this production method. FIG. 12 is a cross-sectional view, and the m-plane nitride-based light-emitting diode 100 has a multilayer structure composed of a plurality of nitride semiconductor layers grown on an m-plane GaN substrate 110. The multilayer structure includes an n-type GaN contact layer 120, an active layer 130, an AlGaN electron-blocking layer 140, a p-type AlGaN layer 150, and an InGaN contact layer 160 arranged in this order from the m-plane GaN substrate 110 side.

The m-plane GaN substrate may be either a just substrate or an off-angled substrate. The off-angle is usually 10 degrees or less, preferably 6 degrees or less. The angle between the thickness direction of each of the nitride semiconductor layers 120 to 160 and the m-axis of the GaN-based semiconductor crystal constituting the layer is equal to the off-angle of the m-plane GaN substrate 110.

The n-type GaN contact layer 120 has been doped with an n-type impurity such as Si or Ge. The thickness thereof is, for example, 1 to 6 μm, preferably 2 to 4 μm. The concentration of the n-type impurity is, for example, 2×10¹⁸ to 2×10¹⁹ cm⁻³, preferably 5×10¹⁸ to 1×10¹⁹ cm⁻³. An n-electrode E110 has been formed on the surface of the n-type GaN contact layer 120 which has been partly exposed.

The active layer 130 may be a single layer constituted of InGaN or InAlGaN. Preferably, however, the active layer 130 is a multiple-quantum-well (MQW) active layer having a structure in which barrier layers and well layers have been alternately superposed. The well layers are constituted preferably of a nitride semiconductor containing In, such as InGaN or InAlGaN. The well layers have a thickness of, for example, 2 to 15 nm, preferably 6 to 12 nm, especially preferably 8 to 10 nm. The barrier layers are constituted of a nitride semiconductor that has a higher band gap energy than the well layers, and the thickness thereof is, for example, 2 to 30 nm, preferably 10 to 20 nm.

The AlGaN electron-blocking layer 140 is constituted of Al_{y}Ga_{1-y}N (preferably 0.08≦y≦0.2) that has a higher band gap energy than both the active layer 130 and the p-type AlGaN layer 150. The thickness thereof is, for example, 10 to 200 nm, preferably 20 nm or more and 50 nm or less. The AlGaN electron-blocking layer 140 can be doped with a p-type impurity such as Mg or Zn, and the impurity concentration is set, for example, at 1×10¹⁹ to 5×10²⁰ cm⁻³. The AlGaN electron-blocking layer 140 can be omitted, and the p-type AlGaN layer 150 can be disposed directly on the active layer 130.

The p-type AlGaN layer 150 is constituted of AlₓGa₁₋ₓN (preferably 0.015≦x≦0.05) and is doped with a p-type impurity such as Mg or Zn. The concentration of the p-type impurity is, for example, 1×10¹⁹ to 5×10²⁰ cm⁻³. The thickness thereof is regulated to, for example, 40 to 200 nm.

The InGaN contact layer 160 has a thickness of, for example, 1 to 20 nm, preferably 10 nm or less, especially 5 nm or less. The composition of the InGaN constituting this layer is preferably set so that the band gap energy of the layer is higher than the band gap energy of the active layer 130 (or than the band gap energy of the well layers in the case where the active layer is MQW).

Incases when an InGaN contact layer 160 is grown subsequently to the p-type AlGaN layer 150 within the same MOCVD furnace, there is a possibility that the InGaN contact layer 160 might be doped with a p-type impurity even without supplying a p-type impurity source to the furnace from the outside. This is because p-type impurity sources such as biscyclopentadienylmagnesium are apt to remain in the furnace.

A light-transmitting electrode E120 constituted of a conductive oxide such as ITO has been formed as an ohmic electrode on the surface of the InGaN contact layer 160. A metallic p-electrode E130 has been formed on part of the light-transmitting electrode E120.

In the nitride-based light-emitting diode 100, it is not essential that the m-plane GaN substrate 110 and the n-type GaN contact layer 120 should adjoin each other. A nitride semiconductor layer having any composition, thickness, and layer configuration can be interposed therebetween. The same applies to between the n-type GaN contact layer 120 and the active layer 130 and between the active layer 130 and the p-type AlGaN layer 150.

The results of experiments conducted by the present inventors will be described below. However, the invention should not be construed as being limited in any way by the methods and sample structures used in these experiments.

### <Experiment 1-1>

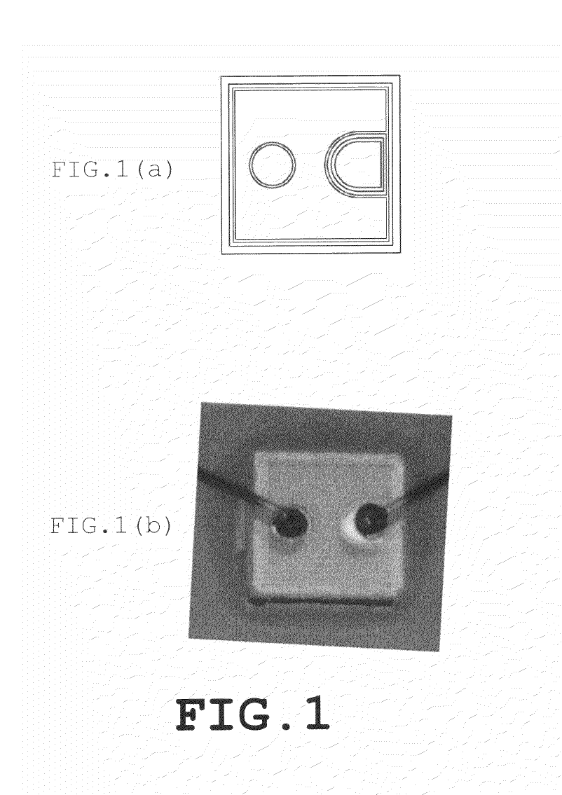

FIG. 1 shows an m-plane nitride-based LED produced in Experiment 1-1 and viewed from the upper surface side. FIG. 1 (a) is a schematic view thereof, and FIG. 1 (b) is a photomicrograph thereof.

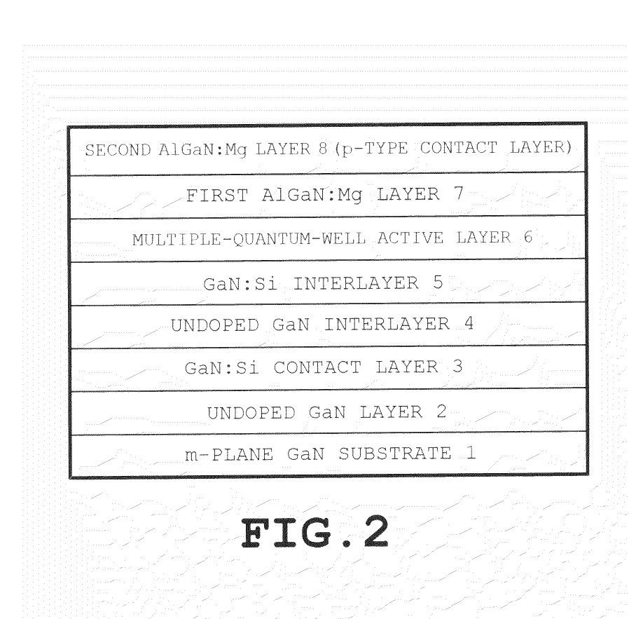

FIG. 2 schematically illustrates the epitaxial layer structure possessed by this m-plane nitride-based LED.

As shown in FIG. 2, this m-plane nitride-based LED has an epitaxial layer structure formed on an m-plane GaN substrate 1, the epitaxial layer structure including, in the following order from the substrate 1 side, an undoped GaN layer 2, a GaN:Si contact layer 3, an undoped GaN interlayer 4, a GaN:Si interlayer 5, a multiple-quantum-well active layer 6, a first AlGaN:Mg layer 7, and a second AlGaN:Mg layer 8 (p-type contact layer).

An m-plane nitride-based LED equipped with such epitaxial layer structure was produced in the following manner.

### (Epitaxial Growth)

First, an m-plane GaN substrate having width, length, and thickness dimensions of 8 mm, 20 mm, and 330 μm was prepared. This substrate had a carrier concentration of 6.8×10¹⁷ cm⁻³ and a +c-direction off-angle of −0.21°.

An undoped GaN layer 2, a GaN:Si contact layer 3, an undoped GaN interlayer 4, a GaN:Si interlayer 5, a multiple-quantum-well active layer 6, a first AlGaN:Mg layer 7, and a second AlGaN:Mg layer 8 were successively epitaxially grown, by an ordinary-pressure MOVPE method, on the surface of the thus-prepared m-plane GaN substrate which had been finished by polishing.

The undoped GaN layer 2 was grown to a thickness of 0.01 μm using TMG (trimethylgallium) and ammonia as raw materials.

The GaN:Si contact layer 3 was grown so as to have an Si concentration of about 7×10¹⁸ cm⁻³ and a thickness of 2.0 μm, using TMG, ammonia, and silane as raw materials.

The undoped GaN interlayer 4 was grown to a thickness of 180 nm using TMG and ammonia as raw materials.

The GaN:Si interlayer 5 was grown so as to have an Si concentration of about 5×10¹⁸ cm⁻³ and a thickness of 20 nm, using TMG, ammonia, and silane as raw materials.

The multiple-quantum-well active layer 6 was formed using TMG, TMI (trimethylindium), and ammonia as raw materials by alternately growing four InGaN barrier layers and three InGaN well layers so that the lowermost layer and the uppermost layer were barrier layers.

The well layer thickness was 3.6 nm, and the barrier layer thickness was 18 nm. No impurity was added to the multiple-quantum-well active layer 6.

The first AlGaN:Mg layer 7 was grown to a thickness of 160 nm using TMG, TMA (trimethylaluminum), ammonia, and biscyclopentadienylmagnesium as raw materials. The flow rates of the TMG and TMA were controlled so as to result in the crystal composition Al_{0.1}Ga_{0.9}N.

The second AlGaN:Mg layer 8 was grown to a thickness of 40 nm using TMG, TMA, ammonia, and biscyclopentadienylmagnesium as raw materials. The flow rates of the TMG and TMA were controlled so as to result in the crystal composition Al_{0.03}Ga_{0.97}N.

During the growth of the second AlGaN:Mg layer 8, the rate of ammonia feeding to the growth furnace was regulated to 10 SLM and the substrate temperature was regulated to 1,070° C. Immediately after completion of the growth of this second AlGaN:Mg layer 8, the heating of the substrate was stopped and the flow rate of the ammonia being fed to the growth furnace was reduced to 0.05 SLM. The ammonia feeding was stopped at the time when the substrate temperature had declined to 970° C. Thereafter, nitrogen gas only was supplied to the growth furnace until the substrate temperature had declined to 500° C.

The carrier gas, substrate temperature, NH₃/TMG ratio, Group-III element source feed rate(s), and growth time which were used for the growth of each layer are collectively shown below in Table 1. The term “NH₃/TMG ratio” means the molar ratio of NH₃ (ammonia) to TMG (trimethylgallium) to be fed to the growth furnace.

TABLE 1

| | | | Substrate | | Group-III element | Growth |
|---|---|---|---|---|---|---|
| | | Carrier | temperature | NH₃/TMG | source feed rate | time |
| | | gas | (° C.) | ratio | (μmol/min) | (min) |
| Undoped GaN layer 2 | | N₂ | 1020 | 3630 | TMG: 123 | 0.67 |
| GaN:Si contact layer 3 | | N₂ | 1020 | 2370 | TMG: 188 | 93 |
| Undoped GaN interlayer 4 | | N₂ | 810 | 4040 | TMG: 111 | 7.2 |
| GaN:Si interlayer 5 | | N₂ | 810 | 4040 | TMG: 111 | 1.5 |
| Multiple-quantum- | Barrier | N₂ | 810 | 43500 | TMG: 14.4 | 8.3 |
| well active layer 6 | layers | | | | TMI: 11.7 | |
| | Well | N₂ | 770 | 43500 | TMG: 14.4 | 4.3 |
| | layers | | | | TMI: 23.4 | |

| | | | | | |
|---|---|---|---|---|---|
| First AlGaN:Mg layer 7 | H₂ + N₂ | 1030 | 5250 | TMG: 85 | 8.4 |
| | | | | TMA: 9.2 | |
| Second AlGaN:Mg layer 8 | H₂ + N₂ | 1070 | 5420 | TMG: 82 | 5.6 |
| | | | | TMA: 2.5 | |

(Formation of p-Side Electrode)

An ITO film having a thickness of 210 nm was formed as a light-transmitting ohmic electrode on the surface (surface of the second AlGaN:Mg layer 8) of the epitaxial wafer obtained in the manner described above. This ITO film was patterned into a given shape using the technique of photolithography and etching. After the pattering, a metallic electrode was formed on part of the ITO film. The metallic electrode was a multilayered film composed of Ti—W (thickness, 108 nm), Au (thickness, 108 nm), Pt (thickness, 89 nm), Au (thickness, 89 nm), Pt (thickness, 89 nm), Au (thickness, 89 nm), Pt (thickness, 89 nm), and Au (thickness, 89 nm) in this order from the side in contact with the ITO film. The metallic electrode was patterned by an ordinary lift-off method.

(Formation of n-Side Electrode)

An n-side metallic electrode was formed on the surface of the GaN: Si contact layer 3 which had been partly exposed by conducting RIE from the front surface side of the epitaxial layers. This n-side electrode was a multilayered film composed of Al (thickness, 500 nm), Ti—W (thickness, 108 nm), Au (thickness, 108 nm), Pt (thickness, 89 nm), Au (thickness, 89 nm), Pt (thickness, 89 nm), Au (thickness, 89 nm), Pt (thickness, 89 nm), and Au (thickness, 89 nm) in this order from the side in contact with the GaN: Si contact layer. The n-side electrode was patterned by an ordinary lift-off method.

After the formation of the n-side electrode, the wafer surface (excluding the surface of the metallic electrode) on the side where the epitaxial layers had been formed was coated with an insulating protective film constituted of SiO₂.

Finally, the wafer was cut using a diamond scriber to thereby obtain 350-μm-square m-plane nitride-based LED chips.

### (Evaluation)

The m-plane nitride-based LED chip obtained in the manner described above was examined for forward voltage (Vf) when a forward-direction current of 20 mA was applied thereto, and the Vf thereof was found to be 3.6 V. In the examination, the current was applied to the LED chip through Au wires connected respectively to the p-side and n-side metallic electrodes.

### <Experiment 1-2>

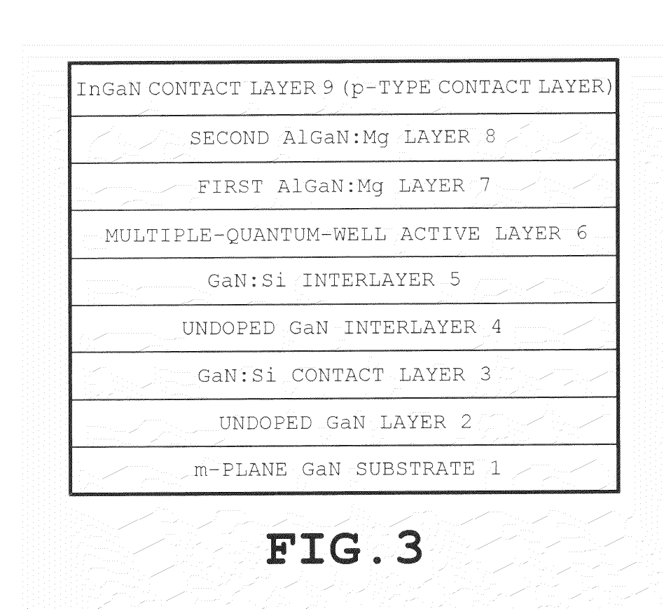

The epitaxial layer structure possessed by the m-plane nitride-based LED experimentally produced in Experiment 1-2 is schematically shown in FIG. 3. This LED was different from the m-plane nitride-based LED experimentally produced in Experiment 1-1 in that an InGaN contact layer 9 had been further grown on the second AlGaN:Mg layer 8.

In Experiment 1-2, immediately after completion of the growth of the second AlGaN:Mg layer 8, the heating of the substrate was stopped and the flow rate of the ammonia being fed to the growth furnace was reduced to 0.05 SLM. Furthermore, the ammonia feeding was stopped at the time when the substrate temperature had declined to 970° C. The procedures up to this step were the same as in Experiment 1-1, but the subsequent procedures differed.

In Experiment 1-2, the heating of the substrate was resumed at the time when the substrate temperature had declined to 820° C., and the InGaN contact layer 9 doped with Mg was grown using TMG, TMI, ammonia, and Cp₂Mg (biscyclopentadienylmagnesium) as raw materials.

The growth conditions for the InGaN contact layer 9 are as shown in Table 2 (in Table 2 are also shown the growth conditions for InGaN contact layers 9 in other experiments). The growth conditions are approximately equal to the growth conditions for the barrier layers included in the multiple-quantum-well active layer 6. Consequently, the thickness of the InGaN contact layer 9 is approximately a value obtained by multiplying the thickness of the barrier layers by [(growth time for the InGaN contact layer)/(growth time for the barrier layers)]. The thickness thereof in Experiment 1-2 was 5 nm.

TABLE 2

| | Growth conditions for InGaN contact layer | | | | | |
|---|---|---|---|---|---|---|
| | | Substrate | | Group-III element | Cp₂Mg | Growth |
| | Carrier | temperature | NH₃/TMG | source feed rate | feed rate | time |
| | gas | (° C.) | ratio | (μmol/min) | (μmol/min) | (s) |
| Experiment 1-2 | N₂ | 820 | 44000 | TMG: 14.4 | 1.2 | 125 |
| Experiment 1-3 | | | | TMI: 11.7 | | |
| Experiment 2-1 | | | | | | |
| Experiment 2-2 | N₂ | 820 | 44000 | TMG: 14.4 | 1.2 | 250 |
| | | | | TMI: 11.7 | | |
| Experiment 2-3 | N₂ | 820 | 44000 | TMG: 14.4 | 1.2 | 500 |
| | | | | TMI: 11.7 | | |
| Experiment 3-1 | N₂ | 820 | 44000 | TMG: 14.4 | 1.2 | 25 |
| Experiment 3-4 | | | | TMI: 11.7 | | |
| Experiment 3-5 | | | | | | |
| Experiment 3-2 | N₂ | 820 | 44000 | TMG: 14.4 | None | 25 |
| | | | | TMI: 11.7 | | |
| Experiment 3-3 | N₂ | 820 | 44000 | TMG: 14.4 | 1.2 | 25 |
| | | | | TMI: 46.8 | | |

The reasons why the value 44,000 was adopted as the NH₃/TMG ratio for the growth of the InGaN contact layers are as follows.

First, in case where the NH₃/TMG ratio is too low, the revaporization of In from the surface of the InGaN crystals being grown occurs in an increased amount and this is presumed to result in an increase in the resistance of contact between the InGaN contact layer to be obtained and an ohmic electrode. From the standpoint of preventing this problem, the NH₃/TMG ratio should be at least 10,000, and is preferably 25,000 or higher, especially 35,000 or higher.

Meanwhile, in case where the NH₃ feed rate is increased to too high a value, the gas flow inside the growth furnace becomes unstable and the control of crystal growth becomes difficult. Consequently, there is a limit in heightening the NH₃/TMG ratio by increasing the NH₃ feed rate. For heightening the NH₃/TMG ratio to a value higher than this limit, a reduction in TMG feed rate may suffice. However, attention should be paid to the fact that a reduction in TMG feed rate is accompanied by a decrease in crystal growth rate. In particular, the m-plane has a strong tendency that as the growth rate decreases, the amount of oxygen to be incorporated into the crystals from the atmosphere increases. In the p-layers, since the oxygen incorporated into the crystals functions to reduce the concentration of p-type carriers, such oxygen incorporation is harmful to the growth of p-type contact layers for which a high carrier concentration is necessary. Nitride semiconductor crystals containing In and Ga have a problem in that as the growth rate decreases, Ga comes to be preferentially incorporated into the crystals and In becomes less apt to be incorporated. From the standpoint of avoiding these problems, it is desirable that the growth rate of the nitride semiconductor crystals containing In and Ga should be regulated to 2 to 3 nm/min.

In the case of ordinary MOVPE devices, NH₃/TMG ratios which can be achieved by heightening the NH₃ feed rate while ensuring the crystal growth rate and while preventing the gas flow inside the growth furnace from becoming unstable are 40,000 to 50,000.

After completion of the growth of the InGaN contact layer 9, the heating of the substrate and the feeding of the ammonia were immediately stopped, and the substrate temperature was lowered to 500° C. or below while supplying nitrogen gas only to the growth furnace.

An epitaxial layer which is the same as in the m-plane nitride-based LED experimentally produced in Experiment 1-1 was grown under the same conditions as in Experiment 1-1 (the growth time also was the same).

The structures of electrodes, etc. were also the same as in Experiment 1-1, except that a p-side electrode was formed on the surface of the InGaN contact layer 9.

The obtained nitride-based LED chip was examined for forward voltage in the same manner as in Experiment 1-1, and the value thereof was found to be 3.5 V.

### <Experiment 1-3>

An m-plane nitride-based LED chip was produced and examined for forward voltage in the same manner as in Experiment 1-2, except for the following.

During the period from immediately after completion of the growth of the first AlGaN:Mg layer 8 to the growth of the InGaN contact layer 9, ammonia was continuously fed to the growth furnace at a rate of 14 SLM.

Immediately after completion of the growth of the InGaN contact layer 9, the heating of the substrate was stopped. Furthermore, ammonia was fed to the growth furnace at a rate of 5 SLM until the substrate temperature declined to 500° C.

The forward voltage of the nitride-based LED chip obtained in this Experiment 1-3 was 3.4 V.

### <Experiment 2-1>

An m-plane nitride-based LED chip was produced and examined for forward voltage in the same manner as in Experiment 1-2, except that use was made of an m-plane GaN substrate 1 having a carrier concentration of 1.6×10¹⁷ cm⁻³ and a +c-direction off-angle of −0.23°.

The forward voltage of the m-plane nitride-based LED chip obtained in this Experiment 2-1 was 3.5 V.

### <Experiment 2-2>

An m-plane nitride-based LED chip was produced and examined for forward voltage in the same manner as in Experiment 2-1, except for the following.

The growth time for the InGaN contact layer 9 was set at 250 seconds (corresponding to 10 nm), which was twice that in Experiment 2-1.

The forward voltage of the m-plane nitride-based LED chip obtained in this Experiment 2-2 was 3.4 V.

The light output (during application of 20 mA) of the m-plane nitride-based LED chip obtained in Experiment 2-2 was 98% of that in Experiment 2-1.

### <Experiment 2-3>

An m-plane nitride-based LED chip was produced and examined for forward voltage in the same manner as in Experiment 2-1, except for the following.

The growth time for the InGaN contact layer 9 was set at 500 seconds (corresponding to 20 nm), which was four times that in Experiment 2-1.

The forward voltage of the m-plane nitride-based LED chip obtained in this Experiment 2-3 was 3.4 V.

The light output (during application of 20 mA) of the m-plane nitride-based LED chip obtained in Experiment 2-3 was 87% of that in Experiment 2-1.

### <Experiment 3-1>

An m-plane nitride-based LED chip was produced and examined for forward voltage in the same manner as in Experiment 1-2, except for the following.

Use was made of an m-plane GaN substrate 1 having a carrier concentration of 2.2×10¹⁷ cm⁻³ and a +c-direction off −angle of 0.01°.

The number of well layers in the multiple-quantum-well active layer 6 was changed to 6.

The growth temperature for the first AlGaN:Mg layer 7 was set at 960° C., and the growth temperature for the second AlGaN:Mg layer 8 was set at 1,000° C.

The growth time for the InGaN contact layer 9 was set at 25 seconds (corresponding to 1 nm in thickness).

After completion of the growth of the InGaN contact layer 9, the heating of the substrate was immediately stopped. Furthermore, ammonia was fed to the growth furnace at a rate of 9 SLM until the substrate temperature declined to 500° C.

The chip size was changed to 500 μm×500 μm, and the electrode patterns were changed accordingly.

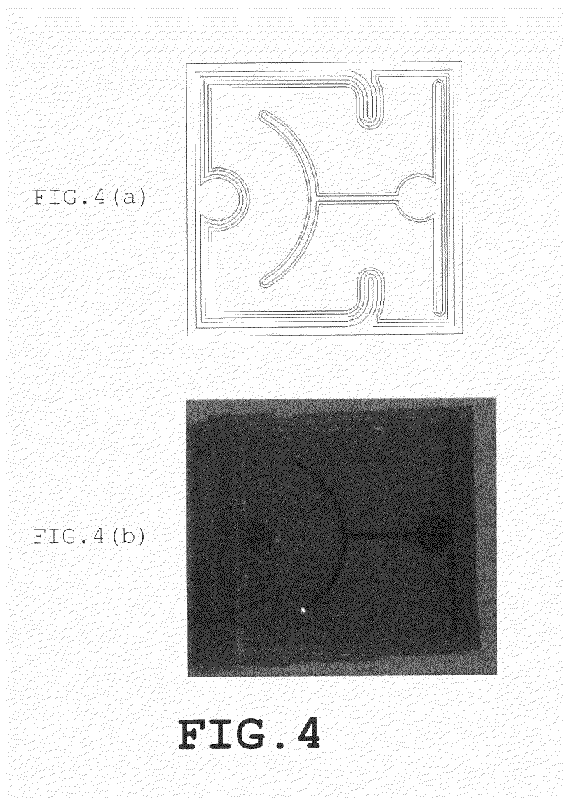

FIG. 4 shows the m-plane nitride-based LED produced in Experiment 3-1 and viewed from the upper surface side. FIG. 4 (a) is a schematic view thereof, and FIG. 4 (b) is a photomicrograph thereof.

The forward voltage of the m-plane nitride-based LED chip obtained in this Experiment 3-1 was 3.4 V.

### <Experiment 3-2>

An m-plane nitride-based LED chip was produced and examined for forward voltage in the same manner as in Experiment 3-1, except for the following.

No Cp₂Mg was fed to the growth furnace when the InGaN contact layer 9 was grown.

The forward voltage of the m-plane nitride-based LED chip obtained in this Experiment 3-2 was 3.4 V.

### <Experiment 3-3>

An m-plane nitride-based LED chip was produced and examined for forward voltage in the same manner as in Experiment 3-1, except for the following.

The rate of TMI feeding to the growth furnace when the InGaN contact layer 9 was grown was increased to 46.8 μmol/min, which was four times that in Experiment 3-1.

The forward voltage of the m-plane nitride-based LED chip obtained in this Experiment 3-3 was 3.4 V.

### <Experiment 3-4>

An m-plane nitride-based LED chip was produced and examined for forward voltage in the same manner as in Experiment 3-1, except for the following.

The growth temperature for the first AlGaN:Mg layer 7 was set at 990° C., and the growth temperature for the second AlGaN:Mg layer 8 was set at 1,030° C.

The forward voltage of the m-plane nitride-based LED chip obtained in this Experiment 3-4 was 3.5 V.

### <Experiment 3-5>

An m-plane nitride-based LED chip was produced and examined for forward voltage in the same manner as in Experiment 3-1, except for the following.

In place of the second AlGaN:Mg layer 8, an InAlGaN:Mg layer was grown at the same temperature to the same thickness.

This InAlGaN:Mg layer was grown at a substrate temperature of 997° C. using a gas mixture of H₂ and N₂ as a carrier gas. The NH₃/TMG ratio during the growth was set at 5,400, and the Group-III element source feed rates were set at 82.3 μmol/min for TMG, 2.46 μmol/min for TMA, and 46.9 μmol/min for TMI. The growth time therefor was set at 5.57 minutes.

The forward voltage of the m-plane nitride-based LED chip obtained in this Experiment 3-5 was as low as 3.3 V. However, the light output (during application of 20 mA) thereof was only 12% of that in Experiment 2-1.

### <Experiment 3-6>

An m-plane nitride-based LED chip was produced and examined for forward voltage in the same manner as in Experiment 3-1, except for the following.

Use was made of an m-plane GaN substrate 1 having a carrier concentration of 2.2×10¹⁷ cm⁻³ and a +c-direction off-angle of −0.05°.

During the step when the InGaN contact layer 9 was grown in Experiment 3-1, none of TMI, TMG, and Cp₂Mg was fed to the growth furnace in Experiment 3-6 (ammonia and the carrier gas were fed in the same manner as in Experiment 3-1).

The forward voltage of the m-plane nitride-based LED chip obtained in this Experiment 3-6 was 4.2 V.

### DISCUSSION

The forward voltages of the m-plane nitride-based LED chips produced in the Experiments described above are collectively shown in Table 3.

TABLE 3

| | Contact | Thickness of InGaN | Vf@20 mA |
|---|---|---|---|
| | layer | contact layer (nm) | (A) |
| Experiment 1-1 | AlGaN | — | 3.6 |
| Experiment 1-2 | InGaN | 5 | 3.5 |
| Experiment 1-3 | InGaN | 5 | 3.4 |
| Experiment 2-1 | InGaN | 5 | 3.5 |
| Experiment 2-2 | InGaN | 10 | 3.4 |
| Experiment 2-3 | InGaN | 20 | 3.4 |
| Experiment 3-1 | InGaN | 1 | 3.4 |
| Experiment 3-2 | InGaN | 1 | 3.4 |
| Experiment 3-3 | InGaN | 1 | 3.4 |
| Experiment 3-4 | InGaN | 1 | 3.5 |
| Experiment 3-5 | InGaN | 1 | 3.3 |
| Experiment 3-6 | AlGaN | — | 4.2 |

The Experiments revealed the following.

Taking into account a comparison between the results of Experiment 1-1 and the results of Experiments 1-2 and 1-3 and from a comparison between the results of Experiment 3-6 and the results of Experiments 3-1 to 3-4, it is considered that to dispose a p-type contact layer constituted of InGaN over AlGaN:Mg layers is useful for reducing the forward voltage of the m-plane nitride-based LED.

In particular, the comparison between the results of Experiment 3-6 and the results of Experiments 3-1 to 3-4 revealed that an InGaN contact layer having a thickness of about 1 nm was able to contribute to a reduction in forward voltage.

The results of Experiments 2-1 to 2-3 suggest that the light output of an m-plane nitride-based LED is adversely affected by too thick an InGaN contact layer.

### <Reference Experiment 1>

In Reference Experiment 1 and Reference Experiment 2, which will be described next, the step of keeping the substrate temperature constant was additionally performed after the growth of an InGaN contact layer.

In Reference Experiment 1, an m-plane nitride-based LED chip was produced and examined for forward voltage in the same manner as in Experiment 1-2, except for the following.

Use was made of an m-plane GaN substrate 1 having a carrier concentration of 6.8×10¹⁷ cm⁻³ and a +c-direction off-angle of −0.08°.

After completion of the growth of the InGaN contact layer 9, the ammonia feeding to the growth furnace was immediately stopped, and the substrate temperature was kept at 820° C. for 10 minutes while supplying nitrogen gas to the growth furnace at a rate of 5 SLM. Thereafter, the heating of the substrate was stopped, and the substrate temperature was lowered to 500° C. or below while supplying nitrogen gas only to the growth furnace.

The forward voltage of the m-plane nitride-based LED chip obtained in this Reference Experiment 1 was 4.0 V.

### <Reference Experiment 2>

An m-plane nitride-based LED chip was produced and examined for forward voltage in the same manner as in Reference Experiment 1, except for the following.

After completion of the growth of the second AlGaN:Mg layer 8, Cp₂Mg was continuously fed to the growth furnace at a feeding rate of 1.2 μmol/min until the growth of an InGaN contact layer 9 was initiated.

The forward voltage of the m-plane nitride-based LED chip obtained in this Reference Experiment 2 was 4.3 V.

From the results of these Reference Experiments 1 and 2, it is considered that to rapidly lower the substrate temperature after the formation of an InGaN contact layer is preferred from the standpoint of reducing the forward voltage.

### <Experiment 4>

In Experiment 4, three m-plane nitride-based LEDs which differed in the composition of the nitride semiconductor crystals constituting the contact layer were experimentally produced. The m-plane nitride-based LEDs were examined for forward voltage and light output.

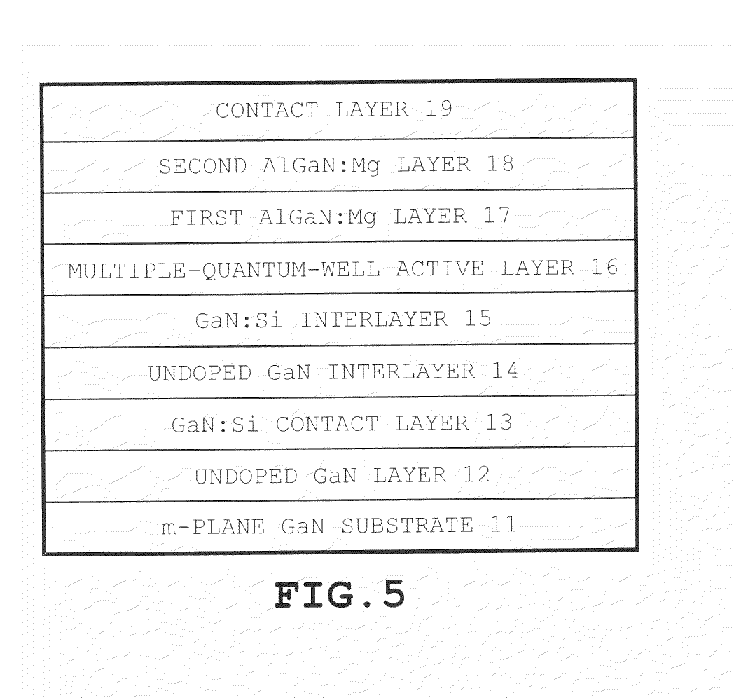

The epitaxial layer structure of the m-plane nitride-based LEDs produced is as shown in FIG. 5, and includes the following layers formed over an m-plane GaN substrate 11 in the following order from the substrate 11 side: an undoped GaN layer 12, a GaN:Si contact layer 13, an undoped GaN interlayer 14, a GaN: Si interlayer 15, a multiple-quantum-well active layer 16, a first AlGaN:Mg layer 17, a second AlGaN:Mg layer 18, and a contact layer 19.

As the m-plane GaN substrate 11, use was made of one having a carrier concentration of 2.0×10¹⁷ to 2.5×10¹⁷ cm⁻³ and a +c-direction off −angle of 0.0°. The layers ranging from the undoped GaN layer 12 to the second AlGaN:Mg layer 18 were grown under the conditions shown in Table 1 as in Experiment 1-1.

After completion of the growth of the second AlGaN:Mg layer 18, the heating of the substrate was immediately stopped, and the flow rate of the ammonia being fed to the growth furnace was reduced to 0.05 SLM. Furthermore, the ammonia feeding was stopped at the time when the substrate temperature had declined to 970° C. Subsequently, at the time when the substrate temperature had declined to 820° C., substrate heating was restarted. Simultaneously therewith, Group-III element sources, ammonia, and Cp₂Mg were fed to grow an Mg-doped contact layer 19.

The three sets of conditions shown in Table 4 were used as growth conditions for the contact layer 19, thereby producing LED 4-1, which had an InGaN contact layer, LED 4-2, which had a GaN contact layer, and LED 4-3, which had an InAlGaN contact layer.

TABLE 4

| | Growth conditions for contact layer | | | | | |
|---|---|---|---|---|---|---|
| | | Substrate | NH₃ | Group-III element | Cp₂Mg | |
| | Carrier | temperature | feed rate | source feed rate | feed rate | Growth time |
| | gas | (° C.) | (L/min) | (μmol/min) | ( μmol/min) | (s) |
| LED4-1 | N₂ | 820 | 14 | TMG: 14.4 | 1.2 | 25 |
| | | | | TMI: 11.7 | | |
| | | | | TMA: 0.0 | | |
| LED4-2 | N₂ | 820 | 14 | TMG: 14.4 | 1.2 | 25 |
| | | | | TMI: 0.0 | | |
| | | | | TMA: 0.0 | | |
| LED4-3 | N₂ | 820 | 14 | TMG: 14.4 | 1.2 | 25 |
| | | | | TMI: 11.7 | | |
| | | | | TMA: 2.5 | | |

After completion of the growth of the contact layer 19, the heating of the substrate and the ammonia feeding were immediately stopped. The substrate temperature was lowered to 500° C. or below while supplying nitrogen gas only to the growth furnace.

After the epitaxial growth step, a p-side electrode, an n-side electrode, and an insulating protective film were formed and dicing was conducted, in the same manner as in Experiment 1-1. The chip size was 500 μm×500 μm, which was the same as that of the m-plane nitride-based LED experimentally produced in Experiment 3-1, and the same electrode patterns as in Experiment 3-1 were adopted.

The luminescent peak wavelengths at the time when a current of 60 mA was applied to LEDs 4-1 to 4-3 were 402 nm, 398 nm, and 399 nm, respectively. LEDs 4-1 to 4-3 were examined for forward voltage and light output, and the results thereof are shown below in Table 5.

TABLE 5

| | | Luminescent | | | | | | |
|---|---|---|---|---|---|---|---|---|
| | | peak | Applied current | | | | | |
| | Composition | wavelength | 20 mA | | 60 mA | | 350 mA | |
| | of contact | at 60 mA | Vf | Light output | Vf | Light output | Vf | Light output |
| | layer | (nm) | (V) | (mW) | (V) | (mW) | (V) | (mW) |
| LED4-1 | InGaN | 402 | 3.30 | 23 | 3.65 | 69 | 4.96 | 378 |
| LED4-2 | GaN | 398 | 3.42 | 20 | 3.79 | 59 | 5.11 | 312 |
| LED4-3 | InAlGaN | 399 | 3.36 | 21 | 3.71 | 60 | 5.31 | 325 |

The InGaN layer has a low band gap energy and has the possibility of serving as an absorption layer. There was hence a fear that the InGaN layer might affect the light output of the m-plane nitride-based LED. However, LED 4-1, which had the InGaN layer as a contact layer, had a higher light output than LED 4-2, which had a GaN layer as a contact layer.

### <Experiment 5>

Comparisons in forward voltage and light output were made between an m-plane nitride-based LED chip (LED 5-1) which had a chip size of 500 μm×500 μm and had an epitaxial layer structure formed using the same growth conditions as in Experiment 3-1 and m-plane nitride-based LED chips of two kinds (LEDs 5-2 and 5-3) obtained by changing part of the structure of LED 5-1.

LED 5-2 was produced so as to have the same structure as LED 5-1, except that the first AlGaN:Mg layer 7 was formed more thinly.

LED 5-3 was produced so as to have the same structure as Sample 5-1, except that use was made of an m-plane GaN substrate 1 having a +c-direction off-angle of −5° and that the first AlGaN:Mg layer 7 was formed more thinly and the second AlGaN:Mg layer 8 was formed more thickly.

LEDs 5-1 to 5-3 were examined for forward voltage and light output, and the results thereof are shown below in Table 6.

TABLE 6

| | Off-angle | Thickness of | Thickness of | | | Light |
|---|---|---|---|---|---|---|
| | of substrate | first AlGaN: | second AlGaN: | Vf@20 | Vf@350 | output @20 |
| | (degrees; | Mg layer 7 | Mg layer 8 | mA | mA | mA |
| | to direction) | (nm) | (nm) | (V) | (V) | (mW) |
| LED5-1 | 0 | 160 | 40 | 3.4 | 4.6 | 21.7 |
| LED5-2 | 0 | 20 | 40 | 3.2 | 4.1 | 24.2 |
| LED5-3 | −5 | 50 | 150 | 3.3 | 4.3 | 25.1 |

### <SIMS Analysis>

By SIMS (secondary-ion mass spectroscopy), the depth-direction distribution of the concentrations of Al, In, and Mg in the vicinity of the surface of each of two epitaxial wafers were examined. One of the wafers is an epitaxial wafer having an InGaN contact layer disposed on a second AlGaN:Mg layer and has the same structure as the epitaxial wafer produced in Experiment 3-1. The other is an epitaxial wafer having a second AlGaN:Mg layer as the uppermost layer of the epitaxial layer structure and has the same structure as the epitaxial wafer produced in Experiment 1-1.

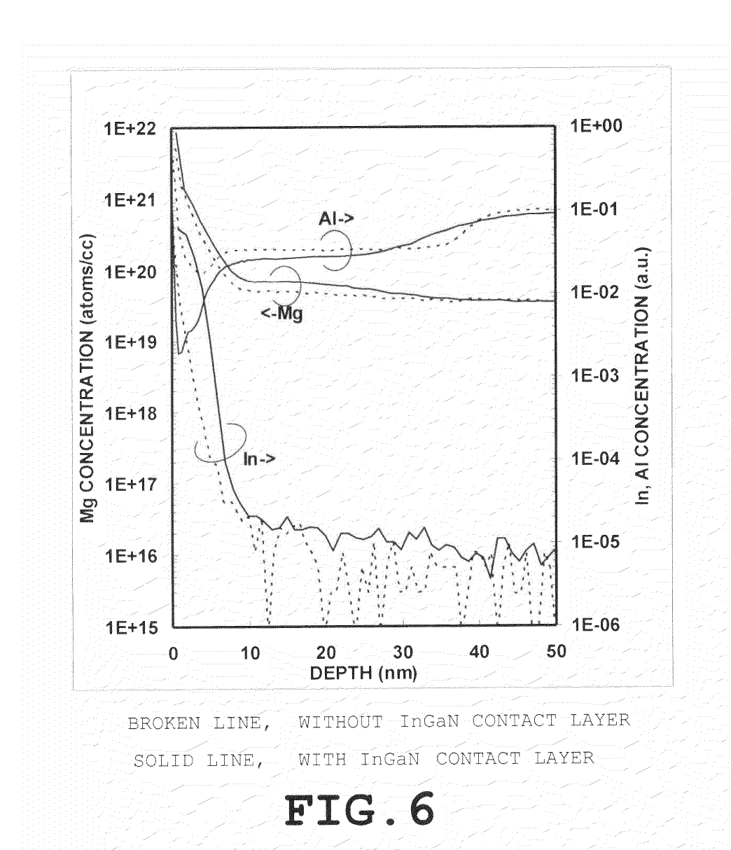

The results are shown in FIG. 6. With respect to each element, the solid line represents a concentration distribution in the epitaxial wafer having an InGaN contact layer disposed therein, while the broken line represents a concentration distribution in the epitaxial wafer having no InGaN contact layer disposed therein.

### <Experiment 6>

An m-plane nitride-based LED equipped with the epitaxial layer structure shown in FIG. 3 was produced in the following manner and evaluated.

### (Epitaxial Growth)

First, an m-plane GaN substrate having width, length, and thickness dimensions of 8 mm, 20 mm, and 330 μm was prepared. This substrate had a carrier concentration of 2.2×10¹⁷ cm⁻³.

An undoped GaN layer 2, a GaN:Si contact layer 3, an undoped GaN interlayer 4, a GaN:Si interlayer 5, a multiple-quantum-well active layer 6, a first AlGaN:Mg layer 7, a second AlGaN:Mg layer 8, and an InGaN contact layer 9 were successively epitaxially grown by an ordinary-pressure MOVPE method, on the surface of the above-prepared m-plane GaN substrate which had been finished by polishing.

The undoped GaN layer 2 was grown to a thickness of 0.01 μm using TMG (trimethylgallium) and ammonia as raw materials. The GaN: Si contact layer 3 was grown so as to have an Si concentration of about 7×10¹⁸ cm⁻³ and a thickness of 2.0 using TMG, ammonia, and silane as raw materials. The undoped GaN interlayer 4 was grown to a thickness of 180 nm using TMG and ammonia as raw materials. The GaN:Si interlayer 5 was grown so as to have an Si concentration of about 5×10¹⁸ cm⁻³ and a thickness of 20 nm, using TMG, ammonia, and silane as raw materials.

The multiple-quantum-well active layer 6 was formed by using TMG, TMI (trimethylindium), and ammonia as raw materials and alternately growing seven InGaN barrier layers and six InGaN well layers so that the lowermost layer and the uppermost layer were barrier layers. The thickness of the InGaN well layers was 3.6 nm (LED 6-1), 6.4 nm (LED 6-2), 9.3 nm (LED 6-3), or 12.4 nm (LED 6-4). The thickness of the InGaN barrier layers was fixed at 18 nm. No impurity was added to the multiple-quantum-well active layer 6.

The first AlGaN:Mg layer 7 was grown to a thickness of 160 nm using TMG, TMA (trimethylaluminum), ammonia, and biscyclopentadienylmagnesium as raw materials. The second AlGaN:Mg layer 8 was grown to a thickness of 40 nm using TMG, TMA, ammonia, and biscyclopentadienylmagnesium as raw materials. The InGaN contact layer 9 was grown using TMG, ammonia, and TMI as raw materials.

The carrier gas, substrate temperature, NH₃/TMG ratio, Group-III element source feed rate(s), and growth time which were used for the growth of each layer are collectively shown below in Table 7. The term “NH₃/TMG ratio” means the molar ratio of the NH₃ (ammonia) to the TMG (trimethylgallium) which were fed to the substrate.

TABLE 7

| | | | Substrate | | Group-III element | Growth |
|---|---|---|---|---|---|---|
| | | Carrier | temperature | NH₃/TMG | source feed rate | time |
| | | gas | (° C.) | ratio | (μmol/min) | (min) |
| Undoped GaN layer 2 | | N₂ | 1020 | 3630 | TMG: 123 | 0.67 |
| GaN:Si contact layer 3 | | N₂ | 1020 | 2370 | TMG: 188 | 93 |
| Undoped GaN interlayer 4 | | N₂ | 810 | 4040 | TMG: 111 | 7.2 |
| GaN:Si interlayer 5 | | N₂ | 810 | 4040 | TMG: 111 | 1.5 |
| Multiple-quantum- | Barrier | N₂ | 810 | 43500 | TMG: 14.4 | 8.3 |
| well active layer 6 | layers | | | | TMI: 11.7 | |
| | Well | N₂ | 770 | 43500 | TMG: 14.4 | 1.7(LED6-1) |
| | layers | | | | TMI: 23.4 | 3.0(LED6-2) |

| | | | | | |
|---|---|---|---|---|---|
| | | | | | 4.3(LED6-3) |
| | | | | | 5.7(LED6-4) |
| First AlGaN:Mg layer 7 | H₂ + N₂ | 960 | 5250 | TMG: 85 | 8.4 |
| | | | | TMA: 9.2 | |
| Second AlGaN:Mg layer 8 | H₂ + N₂ | 1000 | 5420 | TMG: 82 | 5.6 |
| | | | | TMA: 2.5 | |
| InGaN contact layer 9 | N₂ | 820 | 43500 | TMG: 14.4 | 0.42 |
| | | | | TMI: 11.7 | |

After the InGaN contact layer 9 was grown, the heating of the substrate was stopped and NH₃ gas was continuously fed to the growth furnace at a flow rate of 9 SLM until the substrate temperature declined to 500° C.

(Formation of p-Side Electrode)

An ITO film having a thickness of 210 nm was formed as a light-transmitting ohmic electrode on the surface (surface of the InGaN contact layer) of the epitaxial wafer obtained in the manner described above. This ITO film was patterned into a given shape using the technique of photolithography and etching. The patterned ITO film had an area of 177,600 μm² per chip. After the patterning, a metallic electrode was formed on part of the ITO film. The metallic electrode was a multilayered film composed of Ti—W (thickness, 108 nm), Au (thickness, 108 nm), Pt (thickness, 89 nm), Au (thickness, 89 nm), Pt (thickness, 89 nm), Au (thickness, 89 nm), Pt (thickness, 89 nm), and Au (thickness, 89 nm) in this order from the side in contact with the ITO film. The metallic electrode was patterned by an ordinary lift-off method.

(Formation of n-Side Electrode)

An n-side metallic electrode was formed on the surface of the GaN: Si contact layer 3 which had been partly exposed by conducting RIE from the front surface side of the epitaxial layers. This n-side electrode was a multilayered film composed of Al (thickness, 500 nm), Ti—W (thickness, 108 nm), Au (thickness, 108 nm), Pt (thickness, 89 nm), Au (thickness, 89 nm), Pt (thickness, 89 nm), Au (thickness, 89 nm), Pt (thickness, 89 nm), and Au (thickness, 89 nm) in this order from the side in contact with the GaN: Si contact layer. The n-side electrode was patterned by an ordinary lift-off method.

After the formation of the n-side electrode, the wafer surface (excluding the surface of the metallic electrode) on the side where the epitaxial layers had been formed was coated with an insulating protective film constituted of SiO₂.

(Processing of Back Surface of m-Plane GaN Substrate)

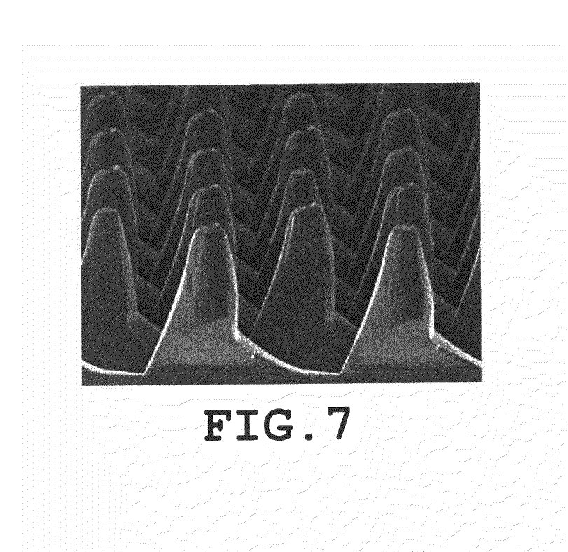

On the back surface of the m-plane GaN substrate 1, a mask pattern was formed, with this mask being configured of circular etching masks constituted of SiO₂ and being disposed respectively on the lattice sites of a triangular lattice. RIE was conducted from above the mask pattern to thereby make the back surface rough. The RIE was conducted to a depth of 6.4 μm. An SEM image of the back surface of the processed m-plane GaN substrate is shown in FIG. 7.

After the processing, the wafer was cut using a diamond scriber to thereby obtain 510-μm-square m-plane nitride-based LED chips.

### (Evaluation)

The m-plane nitride-based LED chips obtained in the manner described above were bonded and affixed to a surface of a white alumina plate using a silicone-based die attach material, and examined for luminescent peak wavelength and light output while applying a pulse current (pulse duration, 1 msec; duty ratio, 1/100) thereto. The current was applied to the LED chips through Au wires connected respectively to the p-side and n-side metallic electrodes. The measurement results are shown in Table 8.

TABLE 8

| | | Applied current | | | | | | | | | | | |
|---|---|---|---|---|---|---|---|---|---|---|---|---|---|
| | Well | 20 mA | | 60 mA | | 100 mA | | 200 mA | | 240 mA | | 350 mA | |
| | layer | | Light | | Light | | Light | | Light | | Light | | Light |
| | thickness | Peak | output | Peak | output | Peak | output | Peak | output | Peak | output | Peak | output |
| | (nm) | wavelength | (mW) | wavelength | (mW) | wavelength | (mW) | wavelength | (mW) | wavelength | (mW) | wavelength | (mW) |
| LED6-1 | 3.6 | 402 | 24 | 402 | 71 | 403 | 116 | 403 | 221 | 403 | 262 | 403 | 379 |
| LED6-2 | 6.4 | 403 | 27 | 403 | 79 | 403 | 129 | 404 | 249 | 404 | 297 | 404 | 429 |
| LED6-3 | 9.3 | 403 | 28 | 403 | 83 | 403 | 137 | 403 | 264 | 403 | 315 | 403 | 454 |
| LED6-4 | 12.4 | 401 | 23 | 401 | 72 | 402 | 120 | 402 | 239 | 402 | 262 | 402 | 413 |

On the assumption that in the m-plane nitride-based LED chips produced in Experiment 6, a value obtained by dividing an applied current by the area of the ohmic electrode (ITO film) is the average current density in the active layer, the average current densities at applied currents of 20 mA, 60 mA, 100 mA, 200 mA, 240 mA, and 350 mA are 11 A/cm², 34 A/cm², 56 A/cm², 113 A/cm², 135 A/cm², and 197 A/cm², respectively.

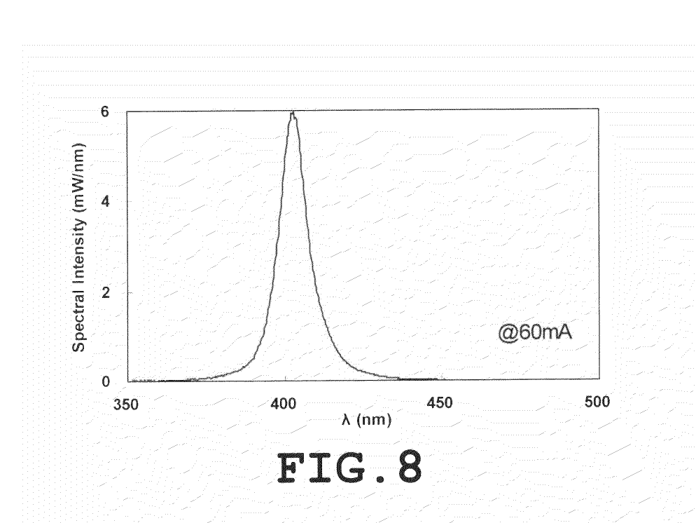

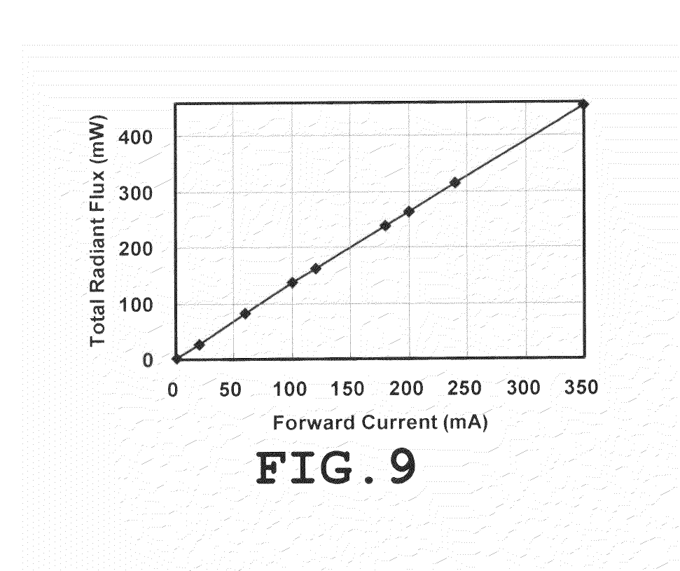

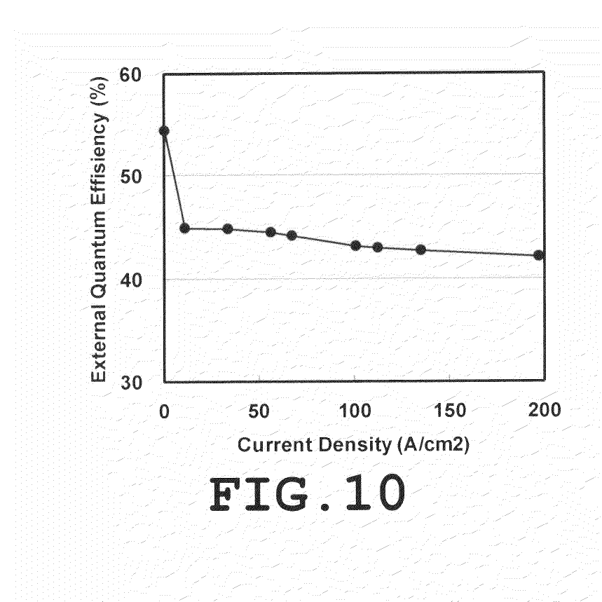

The luminescent spectrum (applied current, 60 mA) and I-L curve of LED 6-3, which had the highest output of the m-plane nitride-based LEDs of four kinds shown in Table 8, are shown respectively in FIG. 8 and FIG. 9. Furthermore, the current density dependence of external quantum efficiency of this LED 6-3 is shown in FIG. 10. In FIG. 10, the abscissa of the graph is the average current density (A/cm²) in the active layer, which was calculated by dividing the current applied to the LED chip by the area of the ohmic electrode (ITO film).

The forward voltages (Vf) of LED 6-3 were as shown below in Table 9.

TABLE 9

| Well layer | | | | | | |
|---|---|---|---|---|---|---|
| thickness: | Applied current | | | | | |
| 9.3 nm | 20 mA | 60 mA | 100 mA | 200 mA | 240 mA | 350 mA |
| Forward | 3.48 | 3.79 | 3.99 | 4.38 | 4.51 | 4.88 |
| voltage (V) | | | | | | |

While the invention has been described in detail and with reference to specific embodiments thereof, it will be apparent to one skilled in the art that various changes and modifications can be made therein without departing from the spirit and scope thereof.

### EXPLANATION OF REFERENCE NUMERALS

100 m-PLANE NITRIDE-BASED LIGHT-EMITTING DIODE
110 m-PLANE GaN SUBSTRATE
120 n-TYPE GaN CONTACT LAYER
130 ACTIVE LAYER
140 AlGaN ELECTRON-BLOCKING LAYER
150 p-TYPE AlGaN LAYER
160 InGaN CONTACT LAYER
E110 n-ELECTRODE
E120 LIGHT-TRANSMITTING ELECTRODE
E130 p-ELECTRODE

1. A method for producing an m-plane nitride-based light-emitting diode,
the method comprising
(i) a step of forming an active layer consisting of a nitride semiconductor over an n-type nitride semiconductor layer in which an angle between the thickness direction and the m-axis of a hexagonal crystal is 10 degrees or less,
(ii) a step of forming an AlGaN layer doped with a p-type impurity over the active layer,
(iii) a step of forming a contact layer consisting of InGaN is formed on the surface of the AlGaN layer, and
(iv) a step of forming an electrode on the surface of the contact layer.

2. The production method according to claim 1, wherein the contact layer has a thickness of 20 nm or less.

3. The production method according to claim 1, which comprises, before forming the AlGaN layer, a step of forming an electron-blocking layer is formed over the active layer, the electron-blocking layer having a thickness of 50 nm or less and consisting of a nitride semiconductor that has a higher band gap energy than the AlGaN layer.

4. The production method according to claim 1, wherein the AlGaN layer comprises AlₓGa₁₋ₓN (0.01≦x≦0.05).

5. The production method according to claim 1, wherein the active layer comprises a well layer and a barrier layer, and the band gap energy of the contact layer is higher than the band gap energy of the well layer.

6. The production method according to claim 1, wherein the electrode comprises a conductive oxide.

7. The production method according to claim 6, wherein the conductive oxide comprises ITO (indium-tin oxide).

8. The production method according to claim 1, wherein the active layer comprises an InGaN well layer and a barrier layer, and the InGaN well layer has a thickness of 6 to 12 nm.

9. The production method according to claim 1, wherein the contact layer is formed at a growth rate of 2 to 3 nm/min.

10. The production method according to claim 1, wherein the contact layer is grown at an NH₃/TMG ratio of 40,000 to 50,000.

11. The production method according to claim 1, wherein the steps (ii) and (iii) are conducted in the same MOVPE growth furnace, and the AlGaN layer is not taken out of the MOVPE growth furnace during the period from the end of the step (ii) to the start of the step (iii).

12. The production method according to claim 11, wherein the AlGaN layer and the contact layer are not subjected to post-annealing during the period from the end of the step (iii) to the start of the step (iv).
